(19) United States
(12) Patent Application Publication
(10) Pub. No.: US 2008/0064194 A1
(43) Pub. Date: Mar. 13, 2008

(54) METHOD FOR FABRICATING FLASH MEMORY DEVICE

(75) Inventor: Dong-Gyun Hong, Ichon-shi (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Icheon-si (KR)

(21) Appl. No.: 11/770,679

(22) Filed: Jun. 28, 2007

(30) Foreign Application Priority Data
Sep. 8, 2006 (KR) 10-2006-0086645

(51) Int. Cl. H01L 21/3205

(52) U.S. Cl. 438/589; 257/E21.24; 257/E21.296

(57) ABSTRACT

A method for fabricating a flash memory device includes providing a semi-finished substrate including a first polysilicon layer electrically isolated by an isolation structure. Recesses are formed in the isolation structure to partially expose sidewalls of the first polysilicon layer. A second polysilicon layer is formed over the exposed first polysilicon layer. Recesses are formed in a portion of the isolation structure not covered by the second polysilicon layer. A dielectric structure is formed over a resultant surface profile obtained after the recesses are formed in the isolation structure. A control gate is formed over the dielectric structure.

### CROSS-REFERENCE TO RELATED APPLICATIONS

The present invention claims priority to Korean patent application number 10-2006-0086645, filed on Sep. 8, 2006, which is incorporated by reference in its entirety.

### BACKGROUND OF THE INVENTION

The present invention relates to a method for fabricating a semiconductor memory device and, more particularly, to a method for fabricating a non-volatile memory device (e.g., a flash memory device).

There is a great demand for flash memory devices that can electronically program and erase data without refreshing data periodically. In an attempt to develop a large capacitance memory device that can store a large amount of data, many researchers are focusing on integration of semiconductor memory devices. The term “programming” indicates an operation of writing data to a memory cell, and the term “erasing” indicates an operation of deleting data stored in a memory cell.

The current large scale integration leads to a decrease in the design rule of flash memory devices. Thus, a programming speed is likely to decrease and an incidence of interference between cells (hereinafter referred to as “cell interference”) is likely to occur. In particular, cell interference is considered a factor that determines a device characteristic more critically in a multi-level cell (MLC) than in a single level cell (SLC). Thus, in consideration of current attention given to the MLC, cell interference needs to be improved.

As the design rule of flash memory devices shift toward minimization, various shallow trench isolation (STI) schemes have been proposed to achieve diverse methods of device isolation. Among the various proposals, a self-aligned floating gate (SAFG) may be limitedly implemented to devices in an MLC due to the difficulty in preventing cell interference. Therefore, an advanced self-aligned shallow trench isolation (ASASTI) scheme is receiving attention as a STI scheme suitable for sub-60 nm MLC devices. As an overlay margin between an active region and a floating gate is decreasing, the ASASTI scheme is being implemented to form floating gates of flash memory devices. With reference to FIGS. 1A to 1C, a typical ASASTI scheme will be described below.

Referring to FIG. 1A, a tunnel oxide layer 11, a polysilicon layer 12 for a floating gate, a buffer oxide layer 13, and a pad nitride layer 14 are formed sequentially on a substrate 10. The pad nitride layer 14, the buffer oxide layer 13, the polysilicon layer 12, the tunnel oxide layer 11, and the substrate 10 are etched to form trenches TRN, each having a certain depth.

The inner surface of each of the trenches TRN is oxidized to form a wall oxide layer 15 thereon. A spin-on glass (SOG) layer 16 is formed to fill the trenches TRN. The SOG layer 16 and the wall oxide layer 15 are chemically and mechanically polished to form an isolation structure 17. The SOG layer 16 is formed because a gap-filling of the isolation structure 17 may be degraded due to an increase in an aspect ratio usually resulting from the thickly deposited polysilicon layer 12.

Referring to FIG. 1B, the pad nitride layer 14 and the buffer oxide layer 13 are removed. The isolation structure 17 may also be removed to a certain thickness. Recesses are formed to a certain death in the isolation structure 17. Reference numerals 15A and 16A represent a remaining wall oxide layer and a remaining SOG layer, respectively. Reference denotation ‘EFH’ represents an effective height of recessed isolation structure 17A. Generally, ‘EFH’ stands for “effective field oxide height,” and in this case, represents the height of a top portion of the recessed isolation structure 17A protruding upward from the surface of the substrate 10. When the ‘EFH’ increases as indicated by a direction ‘A’, a programming operation speed decreases and cell interference is reduced, while programming and erasing operation characteristics (hereinafter referred to as a cycling characteristic) can be improved. On the other hand, when the ‘EFH’ decreases as indicated by a direction of ‘B’, the programming operation speed increases and cell interference is improved, while the cycling characteristic is degraded.

Referring to FIG. 1C, a dielectric layer 18 is formed on a resultant surface profile obtained after the formation of the recessed isolation structure 17A. The dielectric layer 18 may be formed in a structure of oxide/nitride/oxide (ONO). A control gate 19 is formed on the dielectric layer 18, and a tungsten silicide layer 20 is formed to a certain thickness on the control gate 19.

FIG. 2 illustrates a scanning electron microscopic (SEM) image of a flash memory device fabricated using the conventional ASASTI scheme. With reference to FIG. 2, limitations associated with the ASASTI scheme will be described in detail.

When implementing the conventional ASASTI scheme, floating gates need to be formed at a high location, or an isolation structure needs to be formed with a small EFH. Reference denotations ‘F.G.’ and ‘FOX’ represent the floating gates and the isolation structure, respectively. However, as illustrated in FIG. 1A, if the height of the floating gates increases, an aspect ratio of trenches TRN for forming the isolation structure 17 also increases. As a result, the isolation structure 17 is likely to have a degraded gap-filling characteristic. Thus, as illustrated in FIG. 2, when the isolation structure FOX is formed, a SOG layer is generally required to form the normal isolation structure FOX because it is often difficult to fill the trenches TRN with a high density plasma (HDP) oxide layer. Hence, when programming and erasing operations are repetitively performed, a threshold voltage continuously changes. This continuous change often deteriorates the cycling characteristic, resulting in degradation of device reliability.

Also, when the EFH of the isolation structure FOX decreases, the cell interference characteristic may be degraded, and a distance D between a substrate 20 and a control gate may decrease. The decreasing distance D is likely to cause degradation of the cycling characteristic. If only the isolation structure FOX is used to isolate the neighboring floating gates F. G., cell interference is more likely to occur in highly integrated devices. There may not be a STI scheme applied when fabricating a flash memory device having an improved programming operation speed and cell interference to be implemented in sub-60 nm MLC devices.

Additionally, the conventional ASASTI scheme commonly implemented in 70 nm to 120 nm level devices allows a sufficient level of the programming operation speed, cell interference, and the cycling characteristic. However, for sub-60 nm MLC devices, the conventional ASASTI scheme may not be implemented due to an insufficient overlay margin between a floating gate and an active region.

### SUMMARY OF THE INVENTION

Specific embodiments of the present invention provide a method for fabricating a flash memory device that can be implemented in sub-60 nm multi-level cell (MLC) devices.

Specific embodiments of the present invention provide a method for fabricating a flash memory device having an improved programming operation speed, a cell interference characteristic, and a cycling characteristic.

In accordance with one aspect of the present invention, a method for fabricating a flash memory device includes providing a semi-finished substrate including a first polysilicon layer electrically isolated by an isolation structure. Recesses are formed in the isolation structure to partially expose sidewalls of the first polysilicon layer. A second polysilicon layer is formed over the exposed first polysilicon layer. Recesses are formed in the isolation structure not covered by the second polysilicon layer. A dielectric structure is formed over a resultant surface profile obtained after forming recesses in the isolation structure. A control gate is formed over the dielectric structure.

### BRIEF DESCRIPTION OF THE DRAWINGS

FIGS. 1A to 1C are cross-sectional views illustrating a method for fabricating a flash memory device implemented with the conventional advanced self-aligned shallow trench isolation (ASASTI) scheme.

FIG. 2 is a scanning electron microscopic (SEM) image of a flash memory device fabricated using the conventional ASASTI scheme.

FIG. 3A illustrates a cross-sectional view of a flash memory device fabricated using a conventional self-aligned shallow trench isolation (SASTI) scheme.

FIG. 3B illustrates a cross-sectional view of a flash memory device fabricated in accordance with an embodiment of the present invention.

FIGS. 4A to 4E are cross-sectional views illustrating a method for fabricating a flash memory device in accordance with an embodiment of the present invention.

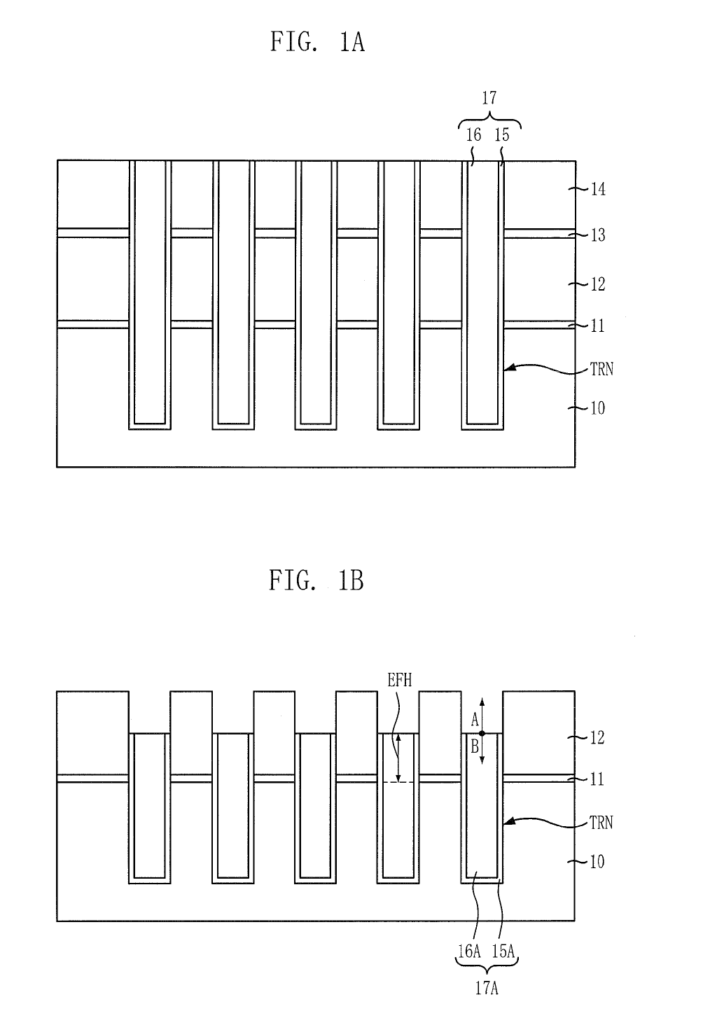

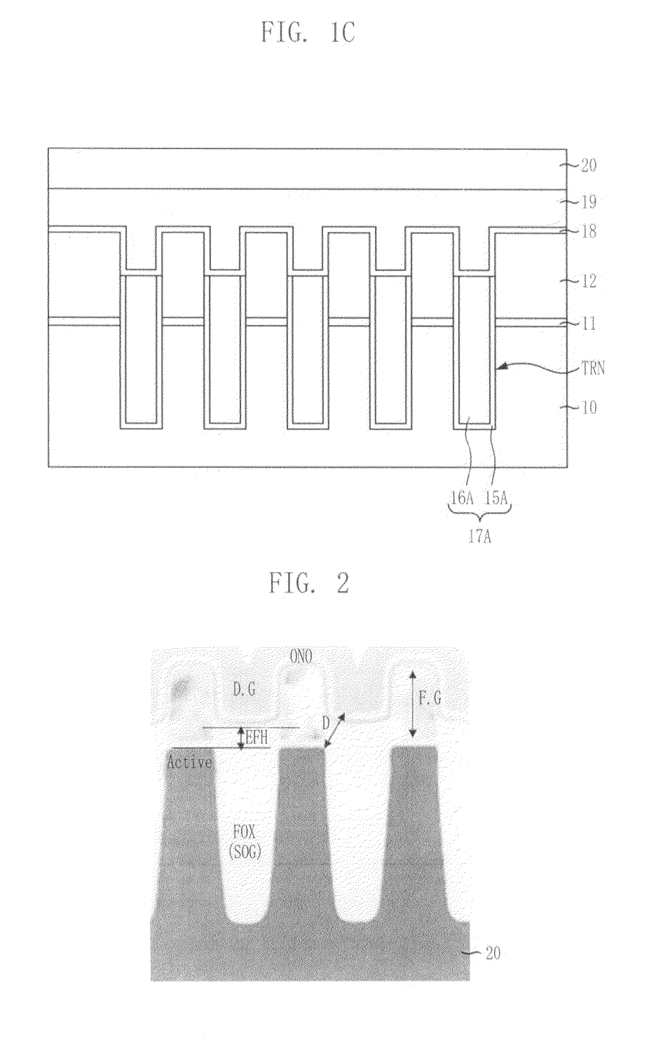

### DESCRIPTION OF SPECIFIC EMBODIMENTS

In the following drawings, the thickness of layers and regions are exaggerated for clarity of the description. When it is described that one layer is formed on another layer or a substrate, the term “on” indicates that the layer may be formed directly on the other layer or the substrate, or a third layer may be interposed therebetween.

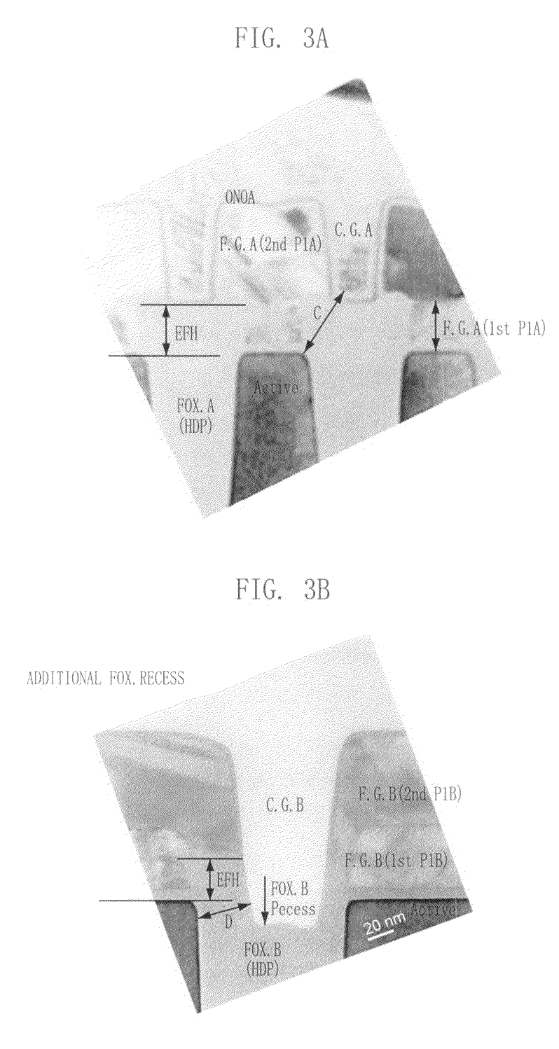

FIG. 3A illustrates a cross-sectional view of a flash memory device fabricated using a conventional self-aligned shallow trench isolation (SASTI) scheme. FIG. 3B illustrates a cross-sectional view of a flash memory device fabricated in accordance with an embodiment of the present invention. In the present embodiment, a SASTI scheme modified from the conventional SASTI scheme is used for the fabrication of a flash memory device.

With reference to FIG. 3B, the flash memory device is implemented with a structure that allows recesses to be formed in an isolation structure FOX.B using the conventional SASTI scheme. Thus, as compared with the conventional ASASTI scheme, a contact area between a floating gate F.G.B and a dielectric structure (not shown) increases so as to increase a coupling ratio. As a result, a programming operation speed increases.

Particularly, in the flash memory device based on the present embodiment, a second polysilicon layer 2nd P1B for the floating gate F.G.B is formed by performing a selective epitaxial growth (SEG) method. Specifically, the second polysilicon layer 2nd P1B is formed differently than a second polysilicon layer 2nd P1A for a floating gate F.G.A. Hence, the flash memory device according to the present embodiment allows the implementation of the conventional SASTI scheme in sub-60 nm devices, which is usually difficult to implement in such small devices due to an insufficient overlay margin between the floating gate and the active region. Also, according to the present embodiment, sub-60 nm MLC devices can also be sufficiently implemented. When the conventional SASTI scheme is implemented, a separate polysilicon layer for a floating gate needs to be deposited and etched. However, using a mask equipment for the deposition and the etching of the separate polysilicon layer is often limited. Thus, an insufficient overlay margin may be observed between the floating gate and the active region.

Referring to FIGS. 3A and 3B, the isolation structure FOX.B formed to isolate the neighboring floating gates F.G.B in the flash memory device according to the present embodiment is recessed deeper than the isolation structure FOX.A in the flash memory device fabricated using the conventional SASTI scheme. The reason for the deeper recessing is to maximally increase the coupling ratio by increasing the contact area between the floating gate F.G.B and the dielectric structure as much as possible. This deeper recessing can increase a programming operation speed. The cell interference can be improved due to the existence of the isolation structure FOX.B and the dielectric structure as an insulation material that isolates the neighboring floating gates F.G.B from each other. The dielectric structure is formed of different material than the material that forms the isolation structure FOX.B.

In particular, the floating gates of the flash memory device according to the present embodiment have substantially the same structure as the floating gates fabricated using the conventional SASTI scheme. This characteristic provides the following advantages. First, as compared with the ASASTI scheme, a gap-filling margin of the isolation structure increases. According to the conventional SASTI scheme, the floating gates are formed in two steps. Thus, during the gap-filling by the isolation structure, the height of the floating gates is lower than that of the floating gates formed using the ASASTI scheme. Hence, instead of a SOG layer, a HDP layer can be used to form the isolation structure, so that the cycling characteristic and reliability of the device can be improved.

Due to the implementation of the conventional SASTI scheme in the present embodiment, as compared with the ASASTI scheme, a sufficient process margin can be secured in relation to the control of EFH, and the threshold voltage change can be minimized to improve device operation characteristics. As reference numerals ‘C’ and ‘D’ (respectively in FIGS. 3A and 3B) show, providing a sufficient distance between the substrate of the active region and the control gate prevents degradation of the cycling characteristic. In consideration of these advantages, the implemented STI scheme in fabricating the flash memory device according to the present embodiment may be an optimal STI Scheme that can be suitably implemented for sub-60 nm MLC devices.

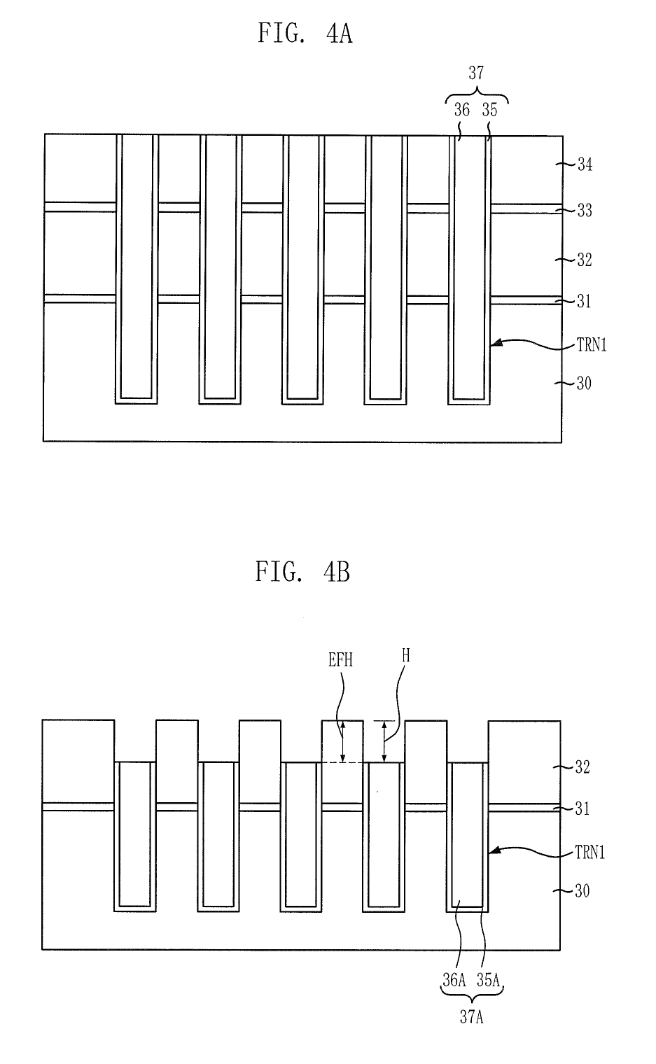

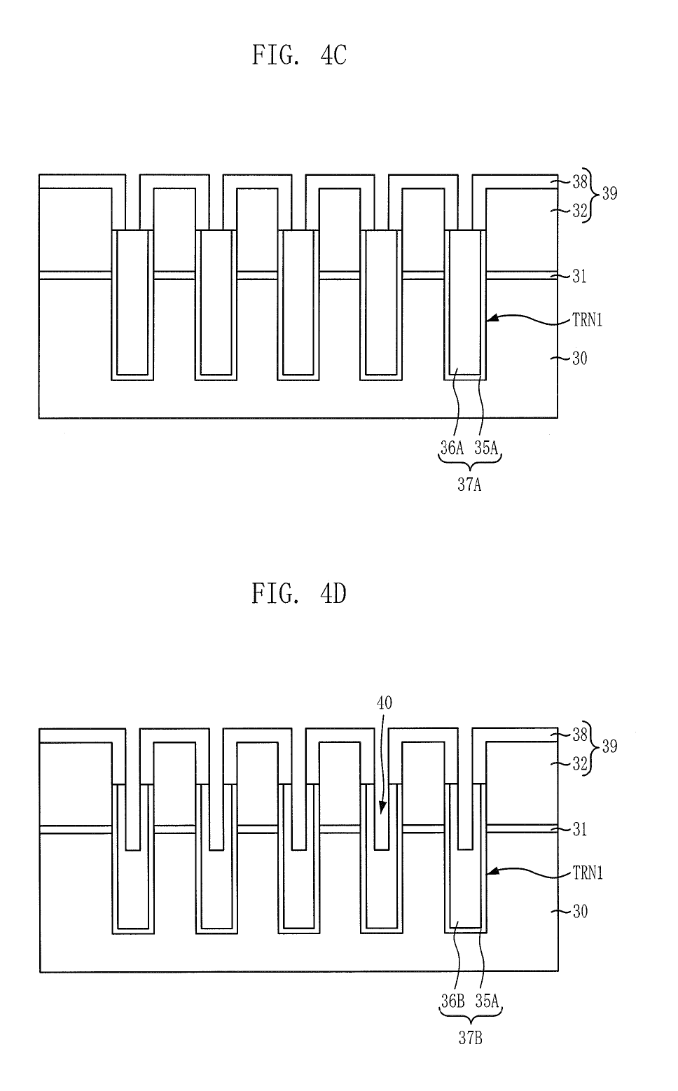

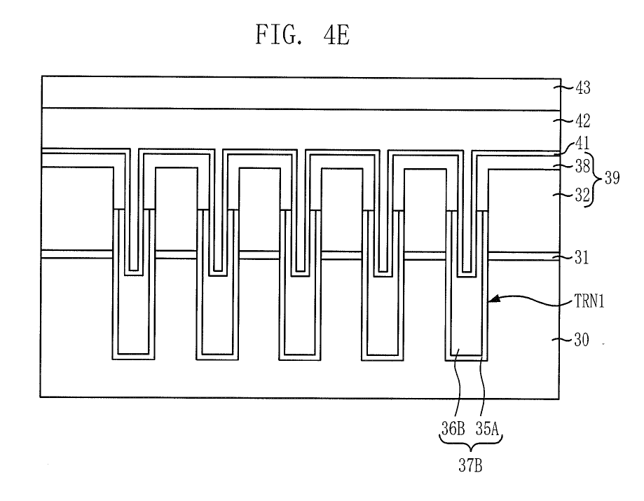

A method for fabricating the flash memory device illustrated in FIG. 3B will be described in detail. FIGS. 4A to 4E are cross-sectional views illustrating the fabrication method of the flash memory device in accordance with an embodiment of the present invention.

Referring to FIG. 4A, a tunneling layer 31, a first polysilicon layer 32 for a floating gate, a buffer layer 33, and a pad layer 34 are formed over a substrate 30. The tunneling layer 31 includes an oxide-based material. The buffer layer 33 and the pad layer 34 include an oxide-based material and a nitride-based material, respectively.

The pad layer 34, the buffer layer 33, the first polysilicon layer 32, the tunneling layer 31, and the substrate 30 are etched to form trenches TRN1, each having a certain depth. The inner surface of the trenches TRN1 is oxidized to form a wall oxide layer 35 thereon. The wall oxide layer 35 is formed to protect damage to the inner sidewalls and a bottom surface of the trenches TRN1 during a STI etching treatment. The wall oxide layer 35 also rounds upper corner portions and decreases a critical dimension (CD) of an active region.

An insulation layer 36 for isolation fills the trenches TRN1. The insulation layer 36 includes an oxide-based material, which is obtained by performing a high density plasma (HDP) treatment. The insulation layer 36 also has a good gap-filling characteristic to prevent generation of a void inside the trenches TRN1. A chemical mechanical polishing (CMP) treatment is performed to form an isolation structure 37 inside the trenches TRN1. Since the isolation structure 37 can be formed using the HDP oxide-based material, the cycling characteristic and the reliability of the device can be improved to a greater extent compared to the conventional scheme.

The above effects can be achieved because an aspect ratio can be reduced by decreasing the thickness of the first polysilicon layer 32 more than that provided by the ASASTI scheme, thereby allowing an increase in the gap-filling margin of the insulation layer 36 when the isolation structure 37 is formed. The thickness of the first polysilicon layer 32 can be reduced because the floating gates are obtained by forming the double polysilicon layers similar to the conventional SASTI scheme. Thus, during the gap-filling of the isolation structure 37, the first polysilicon layer 32 remains at a thickness smaller than that provided by the conventional scheme.

Referring to FIG. 4B, the pad layer 34 and the buffer layer 33 are removed by a wet etching treatment. A certain thickness of the isolation structure 37 may be removed. An additional etching is performed to form recesses in the isolation structure 37 to a certain depth H. Reference denotation ‘EFH’ represents an effective height of a recesses formed in isolation structure 37A. Also, reference numerals 35A and 36A represent a remaining wall oxide layer and a remaining insulation layer, respectively. The processes described in FIGS. 4A and 4B are substantially the same as the processes of the conventional SASTI scheme.

Referring to FIG. 4C, a selective epitaxial growth (SEG) method is applied to form a second polysilicon layer 38 to a certain thickness over the polysilicon layer 32, which protrudes from both sides of the recessed isolation structure 37A. The second polysilicon layer 38 is used as a floating gate. As illustrated, floating gates 39 are formed in the structure in substantially the same way as those formed by the conventional SASTI scheme. For instance, the floating gates 39 formed by the SASTI scheme include two layers of polysilicon. More specifically, the second polysilicon layer 38 is formed to a certain thickness over the first polysilicon layer 32 such that the second polysilicon layer 38 covers a portion of the recessed isolation structure 37A exposed between the protruding and exposed portions of the first polysilicon layer 32.

Referring to FIG. 4D, a pre-cleaning treatment is performed to form recesses in the recessed isolation structure 37A exposed between the floating gates 39 to a certain depth. In other words, recesses 40 are formed to a certain depth inside the recessed isolation structure 37A. Reference numerals 36B and 37B represent a recessed insulation layer and a further recessed isolation structure, respectively. The recesses 40 are formed to maximally increase a contact area of a subsequent dielectric structure 41, so as to increase a coupling ratio as much as possible. Accordingly, a programming operation speed can be increased.

Referring to FIG. 4E, the aforementioned dielectric structure 41 is formed over a resultant surface profile obtained after the formation of the recesses 40. The dielectric structure 41 is formed in an ONO structure. In the present embodiment, in addition to the isolation structure 37, the dielectric structure 41, which is formed of different material than the material used for forming the isolation structure 37, is also formed as the insulation material that isolates neighboring floating gates 39 from each other. Thus, cell interference can be minimized.

After the formation of the dielectric structure 41, a third polysilicon layer 42 for use in a control gate is formed over the dielectric structure 41. A metal silicide layer 43 is formed to a certain thickness over the third polysilicon layer 42 (i.e., the control gate). The metal silicide layer 43 may include a tungsten silicide layer.

According to the embodiments of the present invention, similar to the conventional SASTI scheme, the floating gates are formed in a structure including the first and second polysilicon layers. In particular, the second polysilicon layer is formed based on the SEG method. After formation of the floating gates, recesses are formed to a certain depth in the isolation structure between neighboring floating gates. The dielectric structure, which is formed of different material than the material for the isolation structure, and the control gate are formed over the inner surface of the recessed isolation structure. As a result, the following advantages can be achieved.

First, when the isolation structure is formed, a gap-filling margin of the insulation layer for isolation can increase. Thus, a HDP oxide-based material can be used to form the isolation structure. As a result, the cycling characteristic and device reliability can be enhanced.

Second, the cleaning treatment is performed after the formation of the floating gates to form recesses in the isolation structure exposed between the floating gates to a certain depth. Due to the formation of recesses, the dielectric structure can have a contact area that can be increased as much as possible. This increase in the contact area allows a rapid programming operation speed.

Third, since the dielectric structure is formed of different material than the material for the isolation structure (e.g., insulation material), cell interference can be minimized.

Fourth, compared to the ASASTI scheme, the implementation of the conventional SASTI scheme can provide a sufficient process margin for controlling the EFH. The threshold voltage change can be minimized to improve operation characteristics.

Fifth, since the second polysilicon layer is formed by performing the SEG method to form the floating gates, the conventional SASTI scheme can be implemented in sub-60 nm devices by overcoming the difficulty in implementing the conventional SASTI scheme in sub-60 nm devices particularly associated with the insufficient overlay margin between the floating gate and the active region. Accordingly, it is possible to fabricate flash memory devices having improved programming operation speed, reduced cell interference and good cycling characteristics, so that the SASTI scheme can be implemented in sub-60 nm MLC devices.

While the present invention has been described with respect to various embodiments, it will be apparent to those skilled in the art that various changes and modifications may be made without departing from the spirit and scope of the invention as defined in the following claims.

What is claimed is:

1. A method for fabricating a flash memory device, the method comprising:
providing a semi-finished substrate including a first polysilicon layer electrically isolated by an isolation structure;
forming recesses in the isolation structure that partially expose sidewalls of the first polysilicon layer;
forming a second polysilicon layer over the exposed first polysilicon layer;
forming recesses in a portion of the isolation structure not covered by the second polysilicon layer;
forming a dielectric structure over a resultant surface profile obtained after the recesses are formed in the isolation structure; and
forming a control gate over the dielectric structure.

2. The method of claim 1, wherein forming the second polysilicon layer comprises performing a selective epitaxial growth method.

3. The method of claim 1, wherein forming the recesses in the isolation structure not covered by the second polysilicon layer comprises performing a cleaning treatment.

4. The method of claim 1, wherein providing the semi-finished substrate comprises:
forming a tunneling layer, the first polysilicon layer, a buffer layer, and a pad layer over a substrate;
etching the pad layer, the buffer layer, the first polysilicon layer, the tunneling layer, and the substrate to form trenches;
filling the trenches to form the isolation structure; and
removing the pad layer and the buffer layer.

5. The method of claim 4, wherein forming the isolation structure comprises using a high density plasma oxide-based material.

6. The method of claim 5, further comprising, after forming the control gate, forming a metal silicide layer over the control gate.

7. The method of claim 4, wherein the buffer layer and the tunneling layer each include an oxide-based material.

8. The method of claim 4, wherein the pad layer includes a nitride-based material.

9. The method of claim 6, wherein the metal silicide layer includes tungsten silicide.
